(19) United States
(12) Patent Application Publication
(10) Pub. No.: US 2023/0317704 A1
(43) Pub. Date: Oct. 5, 2023

(54) DISPLAY PANEL AND DISPLAY DEVICE

(71) Applicant: Tianma Advanced Display Technology Institute (Xiamen) Co.,Ltd., Xiamen (CN)

(72) Inventor: Mengmeng Xie, Xiamen (CN)

(73) Assignee: Tianma Advanced Display Technology Institute (Xiamen) Co.,Ltd., Xiamen (CN)

(21) Appl. No.: 18/329,402

(22) Filed: Jun. 5, 2023

(30) Foreign Application Priority Data
Mar. 30, 2023 (CN) 202310328055.4

(51) Int. Cl. H01L 25/16

(52) U.S. Cl. CPC H01L 25/167

(57) ABSTRACT

Provided are a display panel and a display device. The display panel includes a plurality of sub-pixels. The plurality of sub-pixels includes at least one first color sub-pixel, one of which includes M first wirings connected in parallel. The M first wirings include at least one first sub-wiring, and each first sub-wiring includes N light-emitting diodes (LEDs) connected in series, where M and N are positive integers, M≥2, and N≥2.

### CROSS-REFERENCE TO RELATED APPLICATIONS

The present application claims priority to Chinese Patent Application No. 202310328055.4, filed on Mar. 30, 2023, the content of which is incorporated herein by reference in its entirety.

### TECHNICAL FIELD

The present disclosure relates to the technical field of display, and in particular, to a display panel and a display device.

### BACKGROUND

As a new technology, the micro light-emitting diode (Micro-LED) greatly reduces the size of a light-emitting diode. Micro-LED is used in the technical field of display and includes an array of red, blue, and green micro light-emitting diodes capable of emitting light independently. Micro-LED is one of the self-illumination display device. Compared with the organic light emitting diode (OLED) which is another self-illumination display device, Micro-LED has a high efficiency, a long life, and a stable material characteristic not easily affected by environmental conditions. Micro-LED has become a research focus of technical field of display. However, among the current three types of Micro-LED chips, some chips are limited by manufacturing materials, while some chips have a problem of low luminous efficiency. The sub-pixel of the chips with a low luminous efficiency has a low luminance.

### SUMMARY

According to an aspect, embodiments of the present disclosure provide a display panel including a plurality of sub-pixels. The plurality of sub-pixels includes at least one first color sub-pixel, one of the at least one first color sub-pixel includes M first wirings connected in parallel, the M first wirings include at least one first sub-wiring, and each of the at least one first sub-wiring includes N light-emitting diodes (LEDs) connected in series, where M and N are positive integers, M≥2, and N≥2.

According to another aspect, embodiments of the present disclosure provide a display device including a display panel. The display panel includes a plurality of sub-pixels. The plurality of sub-pixels includes at least one first color sub-pixel, one of the at least one first color sub-pixel includes M first wirings connected in parallel, the M first wirings include at least one first sub-wiring, and each of the at least one first sub-wiring includes N light-emitting diodes (LEDs) connected in series, where M and N are positive integers, M≥2, and N≥2

### BRIEF DESCRIPTION OF DRAWINGS

To describe the technical solutions in the embodiments of the present disclosure or in the prior art more clearly, the following briefly describes the accompanying drawings required for describing the embodiments or the prior art. The accompanying drawings in the following description show some embodiments of the present disclosure, and a person skilled in the art may still derive other drawings from these accompanying drawings.

FIG. 1 is a partial schematic diagram of a display panel according to some embodiments of the present disclosure;

FIG. 2 is a partial schematic diagram of another display panel according to some embodiments of the present disclosure;

FIG. 3 is a partial schematic diagram of another display panel according to some embodiments of the present disclosure;

FIG. 4 is a partial schematic diagram of another display panel according to some embodiments of the present disclosure;

FIG. 5 is a schematic cross-sectional view taken along line A-A′ shown in FIG. 1;

FIG. 6 is another schematic cross-sectional view taken along line A-A′ shown in FIG. 1;

FIG. 7 is a partial schematic diagram of another display panel according to some embodiments of the present disclosure;

FIG. 8 is a schematic cross-sectional view taken along line A-A′ shown in FIG. 7;

FIG. 9 is a partial schematic diagram of another display panel according to some embodiments of the present disclosure;

FIG. 10 is a partial schematic diagram of another display panel according to some embodiments of the present disclosure;

FIG. 11 is a partial schematic diagram of another display panel according to some embodiments of the present disclosure;

FIG. 12 is a partial schematic diagram of another display panel according to some embodiments of the present disclosure;

FIG. 13 is a partial schematic diagram of another display panel according to some embodiments of the present disclosure;

FIG. 14 is a partial schematic diagram of another display panel according to some embodiments of the present disclosure;

FIG. 15 is a partial schematic diagram of another display panel according to some embodiments of the present disclosure;

FIG. 16 is a partial schematic diagram of another display panel according to some embodiments of the present disclosure;

FIG. 17 is a partial schematic diagram of another display panel according to some embodiments of the present disclosure;

FIG. 18 is a partial schematic diagram of another display panel according to some embodiments of the present disclosure;

FIG. 19 is a partial schematic diagram of another display panel according to some embodiments of the present disclosure; and

FIG. 20 is a schematic diagram of a display device according to some embodiments of the present disclosure.

### DESCRIPTION OF EMBODIMENTS

In order to make the objectives, technical solutions and advantages of the embodiments of the present disclosure clearer, the technical solutions in the embodiments of the present disclosure will be clearly and completely described below in conjunction with the drawings in the embodiments of the present disclosure. The described embodiments are some, rather than all of the embodiments of the present disclosure. All other embodiments obtained by those of ordinary skill in the art based on the embodiments of the present disclosure should fall within the protection scope of the present disclosure.

Terms used in the embodiments of the present disclosure are only for the purpose of describing specific embodiments, and are not intended to limit the present disclosure. Unless otherwise specified in the context, words, such as “a”, “the”, and “this”, in a singular form in the embodiments of the present disclosure and the appended claims include plural forms.

Conventional display chip has a low luminous efficiency. The luminance of the display chip may be increased by increasing the driving current, but the increase in the driving current inevitably leads to an increase in power consumption. This method of obtaining large luminous by sacrificing power consumption is not recommended. Embodiments of the present disclosure provide a display panel. The sub-pixel includes wirings connected in series. The wiring in series connection includes at least two light-emitting diodes (LEDs) connected in series. In this way, the overall luminous of the wiring in series connection is improved without increasing the driving current, and thus the luminance of the sub-pixel is improved without increasing the power consumption.

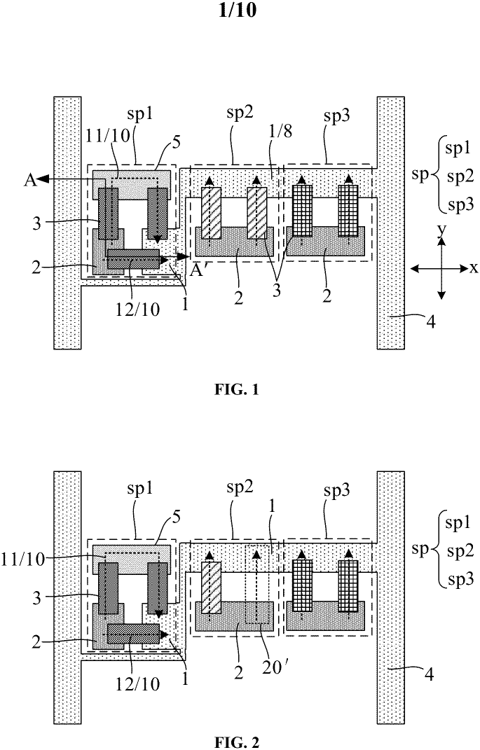

FIG. 1 is a partial schematic diagram of a display panel according to some embodiments of the present disclosure. The display panel includes a plurality of sub-pixels. As shown in FIG. 1, the plurality of sub-pixels sp includes a first color sub-pixel sp1, a second color sub-pixel sp2, and a third color sub-pixel sp3 that emit light of different colors. The sub-pixel sp includes a first electrode 1, a second electrode 2, and at least one LED 3. The first electrodes 1 of the plurality of sub-pixels sp are connected to each other. The second electrodes 2 of the plurality of sub-pixels sp are independent from each other. In some embodiments, the LED 3 is a Micro-LED. In FIG. 1, the LEDs 3 in different color sub-pixels sp are all labeled with the same reference sign 3, but filled with different patterns. The LED 3 in the first color sub-pixel sp1 emits light of a first color, the LED 3 in the second color sub-pixel sp2 emits light of a second color, and the LED 3 in the third color sub-pixel sp3 emits light of a third color. The display panel further includes a first power supply wiring 4 configured to transmit a first power supply signal. The first electrode 1 is connected to the first power supply wiring 4. One of the first electrode 1 and the second electrode 2 is an anode, and the other one is a cathode.

The first color sub-pixel sp1 includes M first wirings 10 connected in parallel. The M first wirings 10 include at least one first sub-wiring 11. The first sub-wiring 11 includes N LEDs 3 connected in series. M and N are both positive integers, M≥2, and N≥2. The LEDs 3 connected in series in the first sub-wiring 11 are electrically connected through a connection electrode 5.

FIG. 1 shows an example in which M=2 and N=2, and the M first wirings 10 include one first sub-wiring 11. In FIG. 1, the dotted wirings with arrows represent the wirings in the sub-pixel sp. As shown in FIG. 1, the second color sub-pixel sp2 includes two wirings connected in parallel, and each wiring includes one LED 3. The third color sub-pixel sp3 includes two wirings connected in parallel, and each wiring includes one LED 3.

In embodiments of the present disclosure, the “wiring’in the sub-pixel sp includes a wiring capable of forming conductive path, and the wiring capable of forming conductive path include the LED 3. For example, as shown in FIG. 1, the first sub-wiring 11 in the first color sub-pixel sp1 includes two LEDs 3, and the formed path is anode→LED 3→LED 3→cathode. The wiring in the second color sub-pixel sp2 is anode→LED 3→cathode.

In some embodiments, the “wiring’ in the sub-pixel sp includes a disconnected wiring, and the disconnected wiring is a redundancy position provided in the sub-pixel sp. FIG. 2 is a partial schematic diagram of another display panel according to some embodiments of the present disclosure. As shown in FIG. 2, the second color sub-pixel sp2 includes two wirings connected in parallel. One wiring is anode→LED 3→cathode, and the other wiring includes the first electrode 1 and the second electrode 2 correspondingly arranged but does not include LED. The wiring does not include the LED is the redundancy position.

The second color sub-pixel sp2 in the display panel may be formed by the following manufacturing method. When manufacturing the display panel, the region for forming the second color sub-pixel sp2 includes a preset position for forming two wirings connected in parallel. First, multiple LEDs 3 are transferred to the corresponding preset positions in the display panel. Each second color sub-pixel sp2 includes one corresponding preset position. That means, all the second color sub-pixels sp2 in the display region of the display panel are manufactured in the same step. After the transferring of LEDs 3 once, each second color sub-pixel sp2 is formed with one wiring. After the transferring of LEDs 3 completes, the light-emitting performances of the second color sub-pixels sp2 are detected. If it is detected that all second color sub-pixels sp2 can emit light normally, no second transferring is performed. The redundancy positions 20′ are kept in the second color sub-pixels sp2. No LED is arranged in the redundancy position 20′, but the redundancy position 20′ is provided with the first electrode 1 and the second electrode 2 that are correspondingly arranged. The disconnected wiring is formed at the redundancy position 20′.

FIG. 2 shows an example in which the third color sub-pixel sp3 includes two wirings connected in parallel, and each wiring includes one LED 3. When manufacturing the display panel, the region for forming the third color sub-pixel sp3 includes a preset position for forming two wirings connected in parallel.

In some embodiments, the two LEDs 3 in the third color sub-pixel sp3 are transferred in two transfer processes respectively. For example, one LED 3 is transferred to the corresponding position of each third color sub-pixel sp3 though the first transfer process, and then the light-emitting performances of the third color sub-pixels sp3 are detected. If it is detected that part of the third color sub-pixels sp3 are defective and cannot emit light normally, the second transfer process is performed. Another LED 3 is transferred to the corresponding position of each third color sub-pixel sp3 though the second transfer process. In this way, each third color sub-pixel sp3 includes two LEDs 3 connected in parallel. After the first transfer process, the defect of the defective third color sub-pixel sp3 may be the defect of the LED transferred to the third color sub-pixel or the defect caused by the transfer process. In the embodiments of the present disclosure, the defective sub-pixel is repaired using the second transfer process, such that all third color sub-pixels sp3 can emit light normally. When the two LEDs 3 in the third color sub-pixel sp3 both can emit light normally, the wiring where one of the two LEDs 3 is located may be regarded as a redundancy wiring.

In some embodiments, the two LEDs 3 in the third color sub-pixel sp3 are transferred through one transfer process. In the one transfer process, two LEDs 3 are transferred to each third color sub-pixel sp3, and the two LEDs 3 are connected in parallel after transferring. When one of the two LEDs 3 connected in parallel is defective due to the transfer process, the other LED 3 can ensure the normal light-emitting of the sub-pixel. When one of the two LEDs 3 connected in parallel becomes defective during use, the other LED 3 can ensure the normal light-emitting of the sub-pixel. That means the third color sub-pixel sp3 includes two wirings connected in parallel, and one of the two wirings is a redundancy wiring.

The description of the redundancy position 20′ is made with taking the second color sub-pixel sp2 in FIG. 2 as an example. The description of the redundancy wiring is made with taking the third color sub-pixel sp3 in FIG. 2 as an example. In some embodiments of the present disclosure, as shown in FIG. 1, the first color sub-pixel sp1 includes a redundancy wiring, a second sub-wiring 12 is connected in parallel with the first sub-wiring 11, the second sub-wiring 12 includes an LED 3, and the second sub-wiring is the redundancy wiring in the first color sub-pixel sp1. In some other embodiments of the present disclosure, the first color sub-pixel sp1 includes a redundancy position. For example, the second sub-wiring 12 does not include the LED 3, and the redundancy position is formed, which is not illustrated by figures.

The first color sub-pixel sp1 in the display panel provided by embodiments of the present disclosure includes at least first wirings 10 that are connected in parallel, the first wiring 10 includes at least one first sub-wiring 11, and the first sub-wiring 11 includes at least two LEDs 3 connected in series. The first color sub-pixel adopts a design that a parallel-connected branch is used as the redundancy branch. Specifically, one first sub-wiring 11 is used as the primary wiring, and another wiring connected in parallel with the primary wiring is used as the redundancy branch. The first sub-wiring 11 includes at least two LEDs 3 connected in series. Compared with a branch including one LED 3, the overall luminance of the first sub-wiring 11 is apparently improved when being supplied a driving current with a same magnitude. In this way, the luminance of the first color sub-pixel sp1 is increased without increasing the power consumption, and thus the low luminance problem of the first color sub-pixel sp1 due to the low inherent luminance efficiency of the LED 3 in the first color sub-pixel sp1 is solved. In addition, the first color sub-pixel sp1 includes a redundancy wiring connected in parallel with the first sub-wiring 11. When the first sub-wiring 11 has emission defect, the LED 3 connected in the redundancy wiring emits light normally, which can ensure the normal light emitting of the first color sub-pixel sp1 and thus ensure the normal use of the display panel. The first color sub-pixel sp1 uses the parallel-connected wiring as the redundancy wiring. During manufacturing, the redundancy wiring can provide a backup for the LED 3 that is defectively transferred, reducing discarded panels and saving cost. Moreover, the redundancy wiring including the LED 3 can compensate the defect of the LED 3 generated in use, thereby prolonging the usage life of the display panel.

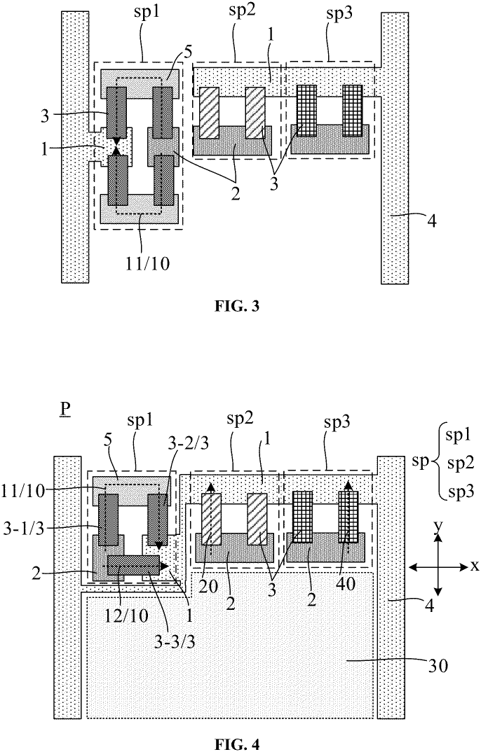

FIG. 1 illustrates an example that the first color sub-pixel sp1 includes one first sub-wiring 11. In another embodiment, M=2, and the two first wirings 10 are both the first sub-wirings 11. FIG. 3 is a partial schematic diagram of another display panel according to some embodiments of the present disclosure. As shown in FIG. 3, the first color sub-pixel sp1 includes two first wirings 10 connected in parallel, the two first wirings 10 are both the first sub-wirings 11, and the first sub-wiring 11 includes two LEDs 3 connected in series.

In some embodiments, the first color sub-pixel sp1 is a red sub-pixel, one of the second color sub-pixel sp2 and the third color sub-pixel sp3 is a blue sub-pixel, and the other one of the second color sub-pixel sp2 and the third color sub-pixel sp3 is a green sub-pixel.

FIG. 4 is a partial schematic diagram of another display panel according to some embodiments of the present disclosure. FIG. 4 shows a region where one pixel unit P is located. In some embodiments, as shown in FIG. 4, one first color sub-pixel sp1, one second color sub-pixel sp2, and one third color sub-pixel sp3 form one pixel unit P. The pixel unit P includes a light-transmitting region 30 and a non-light-transmitting region (not labeled with a reference sign in FIG. 4). The LEDs of the first color sub-pixel sp1, the second color sub-pixel sp2, and the third color sub-pixel sp3 are located in the non-light-transmitting region. In this embodiment, the first color sub-pixel sp1, the second color sub-pixel sp2, and the third color sub-pixel sp3 in the pixel unit P are arranged together, such that the pixel unit P has a large light-transmitting region 30. In this way, the pixel unit P has a large light transmittance, and the display panel with such configuration may be used as a transparent display panel.

In some embodiments, as shown in FIG. 4, the M first wirings 10 in the first color sub-pixel sp1 include at least one second sub-wiring 12, and the second sub-wiring 12 includes only one LED 3. With respect to the first sub-wiring 11, the second sub-wiring 12 may be regarded as a redundancy wiring of the first color sub-pixel sp1. When the first sub-wiring 11 in one first color sub-pixel sp1 has emission defect, the LED 3 in the second sub-wiring 12 emits light to ensure the normal light emitting of this first color sub-pixel sp1. Since the second sub-wiring 12 is configured to include one LED 3, the area occupied by the second sub-wiring 12 is small. In this way, the redundancy emission branch design of the first color sub-pixel sp1 is realized, and it helps reducing the overall area occupied by the first color sub-pixel sp1. Accordingly, the pixel unit P has a large area light-transmitting region 30, and thus the transparency of the display panel is improved when the display panel is applied in transparent display.

In some embodiments, a difference between numbers of LEDs 3 of any two first wirings of the M first wirings 10 is smaller than or equal to 1. In the example embodiment shown in FIG. 1, the first color sub-pixel sp1 includes two first wirings 10, one first wiring 10 includes two LEDs 3, and the other first wiring 10 includes one LED 3. In the example embodiment shown in FIG. 3, the first color sub-pixel sp1 includes two first wirings 10, and each first wiring 10 includes two LEDs 3. When the first wiring 10 in the first color sub-pixel sp1 has emission defect, this first color sub-pixel sp1 is a repaired first color sub-pixel sp1. When the first wirings 10 in the first color sub-pixel sp1 have no emission defect, this first color sub-pixel sp1 is a first color sub-pixel sp1 that does not need to be repaired. When the M first wirings 10 in the first color sub-pixel sp1 each include a LED 3, in the display panel, the actual light-emitting condition of the repaired first color sub-pixel sp1 is different from the actual light-emitting condition of the first color sub-pixel sp1 that does not need to be repaired. In an example in which M=2, only one first wiring 10 in the repaired first color sub-pixel sp1 emits light normally, while two first wirings 10 in the first color sub-pixel sp1 that does not need to be repaired both emit light normally. In the embodiments of the present disclosure, the difference between quantities of LEDs 3 in any two of the M first wirings 10 is configured to be smaller than or equal to 1, and thus a large luminance difference between the repaired first color sub-pixel sp1 and the first color sub-pixel sp1 that does not need to be repaired in the display panel is avoided, thereby preventing the large luminance difference from affecting the display uniformity.

In some embodiments, the LEDs 3 in two first wirings 10 of the M first wirings 10 are all flip-chip type LEDs, and at least one of these two first wirings 10 including the flip-chip type LED is the first sub-wiring. In the flip-chip type LED, the anode and the cathode of the LED are located on the same side of the light-emitting layer. In the example embodiment where M=2, as shown in FIG. 1, the first color sub-pixel sp1 includes two first wirings 10. The two first wirings 10 include a first sub-wiring 11 the LED 3 in which is a flip-chip type LED, and a second sub-wiring 12 the LED 3 in which is also a flip-chip type LED. The first sub-wiring 11 and at least one first wiring 10 connected in parallel with the first sub-wiring 11 are formed using the same type of LED. Since the same type of LED is employed, the manufacturing process is unified, and the cost is low. Moreover, during the transferring of the LEDs, the same transfer process and the same transferring tool may be used, which is beneficial for reducing the manufacturing cost of the display panel.

In some embodiments, all the LEDs in the first color sub-pixel sp1 are of the same type, for example, all are flip-chip type LEDs. Accordingly, all the LEDs in the first color sub-pixel sp1 are manufactured using the same process. Moreover, during the transferring of the LEDs, the same transfer process and the same transferring tool may be used, which is beneficial to reducing the manufacturing cost of the display panel.

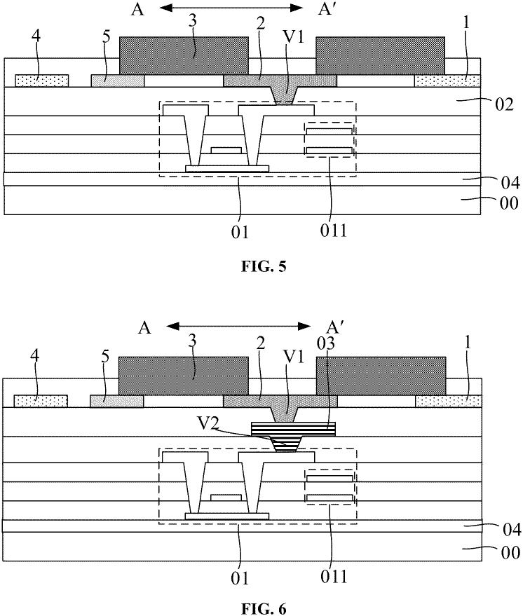

FIG. 5 is a schematic cross-sectional view taken along line A-A′ shown in FIG. 1. In some embodiments, as shown in FIG. 5, the display panel includes a substrate 00 and a pixel circuit 01 located on a side of the substrate 00. The layer where the second electrode 2 is located on a side of the pixel circuit 01 away from the substrate 00. The LED 3 in the sub-pixel sp is located on a side of the layer where the second electrode 2 is located away from the pixel circuit 01. The pixel circuit 01 is electrically connected to the second electrode 2 though a via V1 running through the insulation layer. FIG. 5 just shows one transistor and a storage capacitor 011 in the pixel circuit 01. The specific structure of the pixel circuit 01 is not limited, and the pixel circuit 01 may be any existing type pixel circuit. The first power supply line 4, the first electrode 1, and the second electrode 2 are located in the same layer. With the first electrode 1 and the second electrode 2 being formed in the same layer, during the manufacturing process using the flip-chip type LED, the flip-chip type LED is transferred to the corresponding position between the first electrode 1 and the second electrode 2, and then bonding connection is performed. For example, the bonding connection employs an eutectic layer connection or a conductive adhesive connection. It does not need to perform the electrode forming process after the LED transferring, the process is simple, and a patterning process and its affecting on the formed circuits after the LED transferring are avoided. In embodiments of the present disclosure, the second electrodes 2 of the sub-pixels sp are independent of each other. In each sub-pixel sp, the first electrode 1 is electrically connected to the first power supply line 4. In the layer where the first power supply line 4 is located, the area occupied by the second electrode 2 is small. In a top view, there is a space large enough for forming the first power supply line 4, which is beneficial to reducing the resistance of the first power supply line 4, thereby reducing the voltage drop during the transmission of the first power supply signal and improving the in-panel uniformity.

As shown in FIG. 5, the connection electrode 5, the first power supply line 4, the first electrode 1 and the second electrode 2 are located in the same layer. The connection electrode 5 is located between two LEDs 3 connected in series. The area occupied by the connection electrode 5 is small, and thus the wiring space of the first power supply line 4 is not affected.

As shown in FIG. 5, a buffer layer 04 is arranged between the substrate 00 and the pixel circuit 01. The material of the buffer layer 04 includes an inorganic material. The buffer layer 04 is configured to prevent metal ions from diffusing into the active layers of the transistors in the pixel circuit and thus to reduce the number of defect centers of the transistors and reduce the leakage current.

As shown in FIG. 5, the pixel circuit 01 is electrically connected to the second electrode 2 through the via V1 running though the insulation layer. In the first color sub-pixel sp1, the LED 3 that is in direct electrical connection with the second electrode 2 does not overlap with the first via V1. In the display panel, the insulation layer that is located on a side of the second electrode 2 close to the substrate 00 and is in direct contact with the second electrode 2 is a first planarization layer 02. The first planarization layer 02 is made of an organic material and has a larger thickness compared with the insulation layer made of an inorganic material. The first planarization layer 02 provides a flat surface for a structure formed above the first planarization layer 02. Since the thickness of the first planarization layer 02 is large, the second electrode 2 formed at the position of the first via V1 may have fluctuations. By setting the LED 3 and the first via V1 not overlap, it is avoided that the LED 3 is transferred to an uneven position and affecting the transferring yield.

FIG. 6 is another schematic cross-sectional view taken along line A-A′ shown in FIG. 1. In some embodiments, as shown in FIG. 6, the display panel further includes an intermediate metal 03. The pixel circuit 01 is connected to the intermediate metal 03 though a second via V2 running through the insulation layer, and the intermediate metal 03 is connected to the second electrode 02 through the first via V1 running through another insulation layer. Accordingly, the pixel circuit 01 is connected to the second electrode 02. In this embodiment, a second power supply line may be formed in the same layer with the intermediate metal 03. The second power supply line is configured to transmit a second power supply signal. A power supply terminal of the pixel circuit 01 is connected to the second power supply line. One of the first power supply line 4 and the second power supply line provides a positive power supply voltage, and the other one provides a negative power supply voltage.

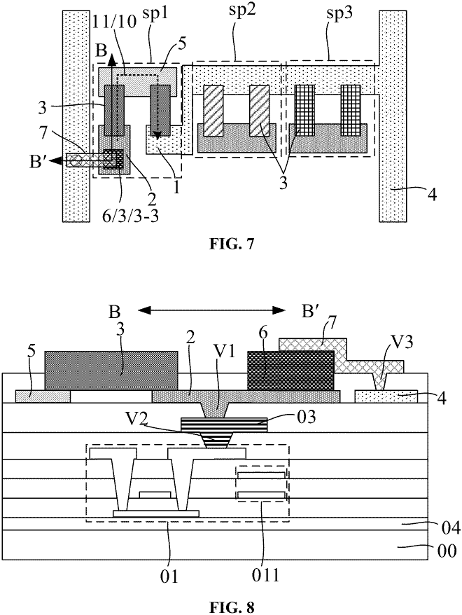

FIG. 7 is a partial schematic diagram of another display panel according to some embodiments of the present disclosure. As shown in FIG. 7, the first color sub-pixel sp1 includes at least one vertical type LED 6. In the vertical type LED 6, the anode and the cathode of the LED are located on two sides of the light-emitting layer respectively. FIG. 7 shows an example in which the first sub-wiring 11 includes two flip-chip type LEDs connected in series, and another first wiring 10 includes one vertical type LED 6. In some embodiments, the first sub-wiring 11 includes a vertical type LED, which will be described in the following embodiments. Compared with the flip-chip type LED, the area occupied by the vertical type LED is smaller. By setting the first color sub-pixel sp1 include at least one vertical type LED, the affecting of the first sub-wiring 11 on the overall area occupied by the first color sub-pixel sp1 is compensated using the advantage of small area of the vertical type LED. Moreover, the affecting of the first sub-wiring 11 on the light-transmitting region of the display panel is reduced, and the overall light transmittance is ensured when the display panel is applied in transparent display.

In some embodiments, the display panel further includes a connection line that is directly connected to the vertical type LED. The connection line is configured to connect the vertical type LED to the corresponding electrode. FIG. 8 is a schematic cross-sectional view taken along line A-A′ shown in FIG. 7. As shown in FIG. 8, a side of the vertical type LED 6 close to the substrate 00 is electrically connected to the second electrode 2, and a side of the vertical type LED 6 away from the substrate 00 is connected to the first power supply line 4 through the connection line 7. The connection line 7 is located on the side of the vertical type LED 6 away from the substrate 00, and is electrically connected to the first power supply line 4 through a third via V3. The manufacturing material of the connection line 7 includes a transparent material such as Indium Tin Oxide (ITO). In this embodiment, the connection line 7 is made of transparent material, so the light transmittance of the connection line 7 is improved, thereby further improving the overall light transmittance of the display panel. When the display panel is applied in transparent display, the transparency of the transparent display is improved.

As shown in FIG. 8, the LED that is directly connected to the second electrode 2 does not overlap with the first via V1. Such configuration can ensure that the LED is transferred to a relatively flat region and improves the transferring yield.

In some embodiments, as shown in FIG. 4, one first color sub-pixel sp1, one second color sub-pixel sp2 and one third color sub-pixel sp3 make up one pixel unit P. In the pixel unit P, the second electrode 2 of the first color sub-pixel sp1, the second electrode 2 of the second color sub-pixel sp2 and the second electrode 2 of the third color sub-pixel sp3 are arranged along the first direction x. That means the three second electrodes 2 in the same pixel unit P are arranged along the same direction. In the display panel, the pixel circuit 01 is connected to the second electrode 2 to provide a voltage to the sub-pixel sp. The pixel circuit 01 is electrically connected to the second electrode 2 though the first via V1 running though the insulation layer. In embodiments of the present disclosure, since the three second electrodes 2 in the same pixel unit P are arranged along the same direction, the pixel circuits 01 are respectively connected to the second electrodes 2 in the corresponding sub-pixels sp in the similar manner (for example the relative position of the pixel circuit 01 with respect to the first via V1), which is convenient for the layout design of the pixel circuits 01 in the display panel. In this way, the pixel circuits 01 may be regularly arranged, the wiring manner of the display panel is simplified, and the difficulty of wiring design is reduced.

As shown in FIG. 4, along the first direction x, the second electrode 2 in the first color sub-pixel sp1 at least partially overlaps with the second electrode 2 in the second color sub-pixel sp2, and the second electrode 2 in the second color sub-pixel sp2 is aligned with the second electrode 2 in the third color sub-pixel sp3. The three second electrodes 2 of the three color sub-pixels sp in the same pixel unit P are substantially arranged along a same straight line, such that the relative positions of the second electrodes 2 in the sub-pixels sp with respect to the corresponding pixel circuits 01 are substantially the same, and the pixel circuits 01 may have a substantially same layout, reducing the process difficulty.

In the embodiment shown in FIG. 4, along the first direction x, there is a partial misalignment between the second electrode 2 in the first color sub-pixel sp1 and the second electrode 2 in the second color sub-pixel sp2.

FIG. 9 is a partial schematic diagram of another display panel according to some embodiments of the present disclosure. FIG. 9 shows a region where one pixel unit P is located. In some embodiments, as shown in FIG. 9, along the first direction x, the second electrode 2 of the first color sub-pixel sp1, the second electrode 2 of the second color sub-pixel sp2 and the second electrode 2 of the third color sub-pixel sp3 are substantially aligned. In this embodiment, the relative positions of the second electrodes 2 in the sub-pixels sp with respect to the corresponding pixel circuits 01 are substantially the same, and the pixel circuits 01 may have a substantially same layout, reducing the process difficulty.

In some embodiments, as shown in FIG. 4, the second color sub-pixel sp2 includes at least two second wirings 20 connected in parallel, and each second wiring 20 includes one LED 3. In the second color sub-pixel sp2, the second wirings 20 are arranged along the first direction x. The third color sub-pixel sp3 includes at least two third wirings 40, and each third wiring 40 includes one LED 3. In the third color sub-pixel sp3, the third wirings 40 are arranged along the first direction x. In this embodiment, the second wirings 20 are arranged along the first direction x, and the third wirings 40 are arranged along the first direction x. In conjunction with the configuration the second electrodes 2 of the three color sub-pixels sp are arranged along the first direction, it is easy to realize that the relative positions of the second electrodes 2 in the sub-pixels sp with respect to the corresponding pixel circuits 01 are substantially the same, and thus the pixel circuits 01 may have a substantially same layout, reducing the process difficulty.

FIG. 4 shows an example embodiment in which the second color sub-pixel sp2 includes two second wirings 20, and the third color sub-pixel sp3 includes two third wirings 40. In other embodiments, the second color sub-pixel sp2 includes more than two second wirings 20, and/or, the third color sub-pixel sp3 includes more than two third wirings 40.

In embodiments of the present disclosure, the first color sub-pixel sp1 includes M first wirings 10, and each of the M first wirings 10 includes one LED 3 electrically connected to the second electrode 2. That means the first color sub-pixel sp1 includes M LEDs electrically connected to the second electrode 2. With such configuration, the M first wirings 10 are connected in parallel. In some embodiments, when the LED 3 connected to the second electrode 2 is a flip-chip type LED, this LED 3 and the second electrode 2 overlap and are electrically connected to each other. When the LED 3 connected to the second electrode 2 is a vertical type LED, this LED 3 overlaps with and is electrically connected to the second electrode 2, or this LED 3 does not overlap with the second electrode 2 but is electrically connected to the second electrode 2 though a connection line. As shown in FIG. 4 and FIG. 9, the M LEDs 3 in the first color sub-pixel sp1 that are electrically connected to the second electrode 2 include a first LED 3-1. The first color sub-pixel sp1 further includes a second LED 3-2 adjacent to the first LED 3-1 along the first direction x. The three sub-pixels sp in the pixel unit P are arranged along the first direction x. In this embodiment, the arrangement direction of the first LED 3-1 and the second LED 3-2 is the same as the arrangement direction of the three sub-pixels sp in the pixel unit P. In this way, the arrangement of the LEDs 3 in the first color sub-pixel sp1 is compact, and the three sub-pixels sp in the pixel unit P are arranged compactly, such that the pixel unit P can have a large light-transmitting region 30. In addition, when the normal light emitting of the first LED 3-1 and the normal light emitting of the second LED 3-2 contribute to the light emitting of the first color sub-pixel sp1, it is ensured that the color mixing of the light of the first color sub-pixel sp1 and the light of other sub-pixels sp is more uniform.

As shown in FIG. 4 and FIG. 9, each of the second color sub-pixel sp2 and the third color sub-pixel sp3 includes wirings connected in parallel, two LEDs 3 in the second color sub-pixel sp2 connected in parallel with each other are arranged along the first direction x, and the two LEDs 3 in the third color sub-pixel sp3 connected in parallel with each other are also arranged along the first direction x. The arrangement direction of the first LED 3-1 and the second LED 3-2 in the first color sub-pixel sp1 is the same as the arrangement directions of the LEDs in other sub-pixels sp. In conjunction with the configuration the second electrodes 2 of the three color sub-pixels sp in the pixel unit P are arranged along the first direction x, the layout of the LEDs 3 in the first color sub-pixel sp1 is the same as the layouts of the LEDs 3 in other color sub-pixels sp, which simplifies the wiring manner of a driving current in the display panel.

In some embodiments, as shown in FIG. 4, the first LED 3-1 and the second LED 3-2 are connected in series in one first sub-wiring 11, the second electrode 2 and the first electrode 1 in the first color sub-pixel sp1 are adjacent to each other along the first direction x, and the second LED 3-2 is electrically connected to the first electrode 1. FIG. 4 shows an example in which the first LED 3-1 and the second LED 3-2 are connected in series through the connection electrode 5, and the first LED 3-1 and the second LED 3-2 may emit light simultaneously. In addition, the arrangement direction of the first LED 3-1 and the second LED 3-2 is the same as the arrangement direction of the three sub-pixels sp in the pixel unit P. When the first sub-wiring 11 including the first LED 3-1 and the second LED 3-2 emits light normally, the luminance of the first color sub-pixel sp1 is increased to compensate the inherent low luminance efficiency of the first color LED chip, and the color mixing of the light of the first color sub-pixel sp1 and the light of other sub-pixels sp is more uniform.

As shown in FIG. 4, the first color sub-pixel sp1 further includes a third LED 3-3, and the third LED 3-3 includes a first end electrically connected to the second electrode 2 and a second end electrically connected to the same first electrode 1 with the second LED 3-2. The third LED 3-3, the first LED 3-1 and the second LED 3-2 are arranged in a shape of a Chinese Character “ [symbol] ”. In this embodiment, the third LED 3-3 is located separately in one first wiring 10, and the first wiring 10 is connected in parallel with the first sub-wiring 11 including the first LED 3-1 and the second LED 3-2. The first wiring 10 including the third LED 3-3 is the redundancy wiring of the first color sub-pixel sp1. When the emission of the first sub-wiring 11 is defective, the third LED 3-3 bonded in the redundancy wiring emits light normally to ensure the normal light emitting of the first color sub-pixel sp1 and ensure the normal use of the display panel. During the manufacturing process, the redundancy wiring provides a backup for the LED in the first sub-wiring 11 that is defectively transferred, reducing discarded panels and saving cost. In addition, the redundancy wiring including the third LED 3-3 can compensate the defective LED generated in use, thereby prolonging the usage life of the display panel. Moreover, since the three LED 3 in the first color sub-pixel sp1 are arranged in a shape of a Chinese Character “ [symbol] ”, the arrangement of the LEDs 3 is compact, and the pixel unit P can have a large light-transmitting region 30, improving the display effect when the display panel is applied in the transparent display.

In the embodiment shown in FIG. 4, the second electrode 2 of the first color sub-pixel sp1 and the second electrode 2 of another sub-pixel sp are spaced apart by the first electrode 1 of the first color sub-pixel sp1.

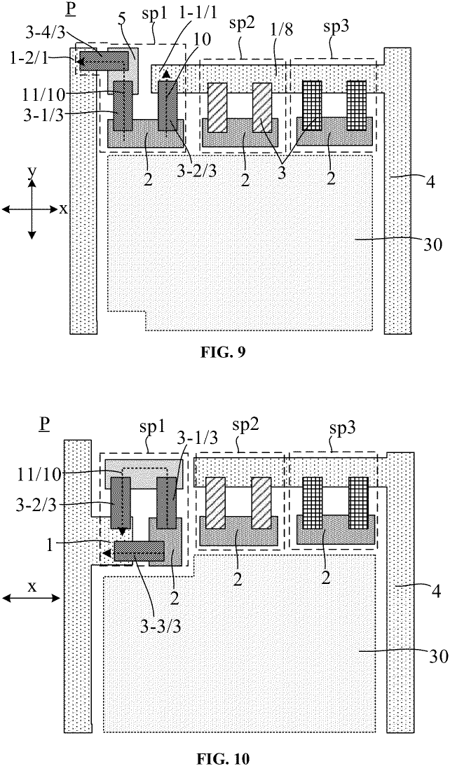

FIG. 10 is a partial schematic diagram of another display panel according to some embodiments of the present disclosure. In some embodiments, as shown in FIG. 10, the first LED 3-1 and the second LED 3-2 are connected in series in one first sub-wiring 11, and the second end of the third LED 3-3 and the second LED 3-2 are connected to the same first electrode 1. The third LED 3-3, the first LED 3-1 and the second LED 3-2 are arranged in a shape of a Chinese Character “ [symbol] ”. In the pixel unit P, the second electrode 2 of the first color sub-pixel sp1 is adjacent to the second electrode 2 of another sub-pixel sp.

FIG. 11 is a partial schematic diagram of another display panel according to some embodiments of the present disclosure. In some embodiments, as shown in FIG. 11, the three second electrodes 2 in the pixel unit P are arranged along the first direction x, and the first power supply line 4 extending along a second direction y intersecting with the first direction x. The first electrode 1 is connected to the first power supply line 4. The first LED 3-1 and the second LED 3-2 are connected in series in one first sub-wiring 11, and are adjacent to each other along the first direction x. The first LED 3-1 is electrically connected to the second electrode 2. One end of the third LED 3-3 is electrically connected to the second electrode 2. The first wiring 10 where the third LED 3-3 is arranged includes only one LED 3. The first electrode 1 in the first color sub-pixel sp1 includes a first sub-electrode 1-1 and a second sub-electrode 1-2. The second LED 3-2 is electrically connected to the first sub-electrode 1-1. The first sub-electrode 1-1 and the second electrode 2 are arranged along the first direction x. Another end of the third LED 3-3 is electrically connected to the second sub-electrode 1-2. A segment of the first power supply line 4 is reused as the second electrode 1-2. In this embodiment, the first wiring 10 including the third LED 3-3 and the first sub-wiring 11 are connected to different positions of the first electrode 1. As shown in FIG. 11, the third LED 3-3 is positioned as follows. The third LED 3-3 is only adjacent to the first LED 3-1 along the second direction y, and a segment of the first power supply line 4 is reused as the second sub-electrode 1-2. By setting the third LED 3-3 be electrically connected to the second sub-electrode 1-2, the affecting of the third LED 3-3 on the area of the light-transmitting region 30 in the pixel unit P is reduced. In addition, the sizes of the first sub-electrode 1-1 connected to the second LED 3-2 can be set relatively small, which is also beneficial to increasing the area of the light-transmitting region 30. In this embodiment, the first sub-pixel sp1 has small affecting on the area of the light-transmitting region 30, ensuring a high transparency of the transparent display when the display panel is applied in the transparent display.

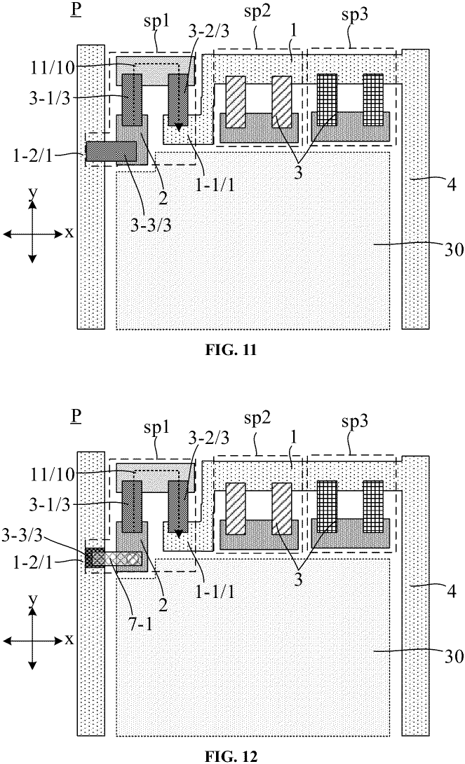

In some other embodiments, the third LED 3-3 is in one first wiring 1, and the third LED 3-3 is a vertical type LED. FIG. 12 is a partial schematic diagram of another display panel according to some embodiments of the present disclosure. As shown in FIG. 12, a first end of the third LED 3-3 is connected to the first electrode 1, and a second end of the third LED 3-3 is connected to the second electrode 2. The third LED 3-3 is a vertical type LED, and overlaps with and is electrically connected to the first power supply line 4. The second end of the third LED 3-3 is electrically connected to the second electrode 2 through a first connection line 7-1. Optionally, the first connection line 7-1 is made of a transparent material. In this embodiment, the third LED 3-3 is a vertical type LED, so the affecting of the third LED 3-3 on the area of the light-transmitting region 30 in the display unit P is reduced. Moreover, the third LED 3-3 overlaps with the first power supply line 4, that means the third LED 3-3 and the first power supply line 4 are located in the same region. As a result, the area of the arrangement region of each LED is reduced, which further improves the light transmittance of the pixel unit P.

In some other embodiments, as shown in FIG. 7, the vertical type LED 6 is arranged in one first wiring 10, and the vertical type LED 6 is the third LED 3-3. In this embodiment, the third LED 3-3 and the second electrode 2 overlap and are electrically connected to each other. One end of the third LED 3-3 is electrically connected to the first power supply line 4 through the connection line 7.

In some embodiments, as shown in FIG. 9, the first LED 3-1 and the second LED 3-2 are respectively arranged in two first wirings 10, and are respectively electrically connected to the second electrode 2. The first LED 3-1 is arranged in one first sub-wiring 11, and the first sub-wiring 11 including the first LED 3-1 further includes a fourth LED 3-4. The fourth LED 3-4 and the first LED 3-1 are arranged along the second direction y. In this embodiment, the first LED 3-1 and the second LED 3-2 are respectively electrically connected to the second electrode 2. When the second color sub-pixel sp2 and the third color sub-pixel sp3 each include wirings connected in parallel, the second electrodes 2 in the three color sub-pixels sp have a substantially same shape. In conjunction with the configuration the second electrodes 2 of the three color sub-pixels sp are arranged along the same direction, it is easy to realize that the relative positions of the second electrodes 2 in the sub-pixels sp with respect to the corresponding pixel circuits 01 are substantially the same, which is convenient to the layout design of the pixel circuit in the display panel and the reduction of the wiring design.

As shown in FIG. 9, the display panel includes first power supply lines 4 extending along the second direction y and an auxiliary power supply line 8 extending along the first direction x. The first electrode 1 is connected to the first power supply line 4. At least one end of the auxiliary power supply line 8 is electrically connected to one first power supply line 4. The auxiliary power supply line 8 and the first power supply line 4 transmit a same voltage signal. The first electrode 1 of the first color sub-pixel sp1 includes a first sub-electrode 1-1 and a second sub-electrode 1-2. The second LED 3-2 is electrically connected to the first sub-electrode 1-1. A segment of the auxiliary power supply line 8 is reused as the first sub-electrode 1-1. One end of the fourth LED 3-4 is electrically connected to the second sub-electrode 1-2. A segment of the first power supply line 4 is reused as the second sub-electrode 1-2. In this embodiment, two first wirings 10 connected in parallel are respectively connected to different positions of the first electrode 1. The fourth LED 3-4 is positioned in the following manner. As shown in FIG. 9, the fourth LED 3-4 and the first LED 3-1 are arranged along the second direction y. A segment of the first power supply line 4 is reused as the second sub-electrode 1-2. By setting the fourth LED 3-4 be electrically connected to the second sub-electrode 1-2, the affecting of the fourth LED 3-4 on the area of the light-transmitting region 30 in the pixel unit P is reduced. Moreover, the sizes of the first sub-electrode 1-1 connected to the second LED 3-2 can be set relatively small, which is also beneficial to increasing the area of the light-transmitting region 30. In this embodiment, the first sub-pixel sp1 has small affecting on the area of the light-transmitting region 30, ensuring a high transparency of the transparent display when the display panel is applied in the transparent display.

In addition, as shown in FIG. 9, the second color sub-pixel sp2 includes two LEDs 3 connected in parallel with each other. The LED 3 has a first end electrically connected to the second electrode 2 and a second end electrically connected to the auxiliary power supply line 8. A segment of the auxiliary power supply line 8 is reused as the first electrode 1 of the second color sub-pixel sp2. The third color sub-pixel sp3 and the second color sub-pixel sp2 have a same structure. Another segment of the auxiliary power supply line 8 is reused as the first electrode 1 of the third color sub-pixel sp3.

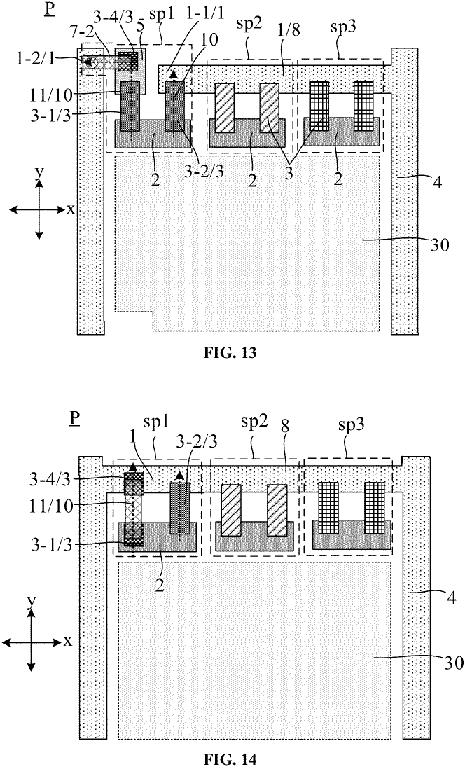

In the embodiment shown in FIG. 9, the fourth LED 3-4 is a flip-chip type LED. In some other embodiments, the fourth LED 3-4 is a vertical type LED. FIG. 13 is a partial schematic diagram of another display panel according to some embodiments of the present disclosure. As shown in FIG. 13, the fourth LED 3-4 is a vertical type LED, and the fourth LED 3-4 and the first LED 3-1 are connected in series through the connection electrode 5. The fourth LED 3-4 and the connection electrode 5 overlap and are electrically connected to each other. The fourth LED 3-4 is also electrically connected to the first power supply line 4 through a second connection line 7-2. Optionally, the second connection line 7-2 is made of a transparent material. In this embodiment, the fourth LED 3-4 is a vertical type LED, which can further reduce the affecting of the fourth LED 3-4 on the area of the light-transmitting region 30 in the pixel unit P and increase the light transmittance of the pixel unit P.

In some embodiments, the fourth LED 3-4 and the first LED 3-1 are connected in series through the connection electrode 5. The fourth LED 3-4 and the first power supply line 4 overlap and are electrically connected. The fourth LED 3-4 is further electrically connected to the connection electrode 5 though a connection line. Such configuration is not shown by figures.

FIG. 14 is a partial schematic diagram of another display panel according to some embodiments of the present disclosure. In some embodiments, as shown in FIG. 14, the first LED 3-1 and the fourth LED 3-4 in the first sub-wiring 11 are connected in series, and the first LED 3-1 and the fourth LED 3-4 are both vertical type LEDs. Another first wiring 10 of the first color sub-pixel sp1 includes a second LED 3-2 that is a flip-chip type LED. The first LED 3-1 and the second electrode 2 overlap and are electrically connected. The fourth LED 3-4 and an auxiliary power supply line 8 overlap and are electrically connected. The auxiliary power supply line 8 has two ends each connected to one first power supply line 4. In this embodiment, the arrangement of the first sub-wiring 11 can improve the luminance of the first color sub-pixel sp1 and solve the low luminance efficiency problem of one single LED 3. Moreover, the area occupied by the first sub-wiring 11 is small, which is conducive to reducing the area occupied by the first color sub-pixel sp1 and reducing the influence on the light-transmitting region 30 in the pixel unit P. In addition, in the embodiment shown in FIG. 14, the two first wirings 10 in the first color sub-pixel sp1 that are connected in parallel are arranged along the first direction, several segments of the auxiliary power supply line 8 are reused as the first electrodes 1 of the sub-pixels sp, and each of the two ends of the auxiliary power supply line 8 is electrically connected to one first power supply line 4, thereby reducing the voltage drop during the transmission of the first power supply signal and improving the in-plane uniformity.

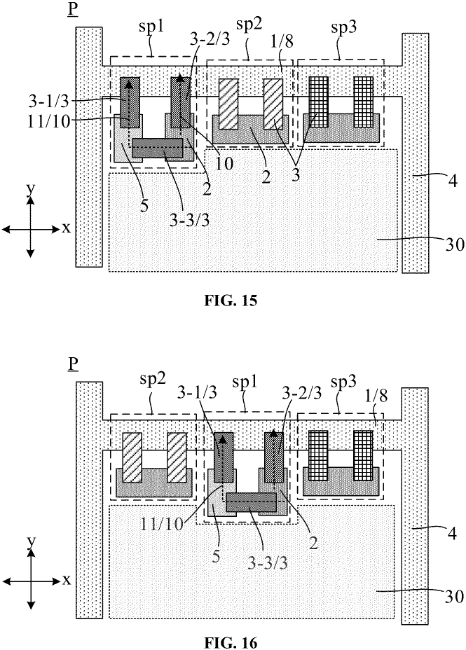

FIG. 15 is a partial schematic diagram of another display panel according to some embodiments of the present disclosure. In some embodiments, as shown in FIG. 15, the first LED 3-1 and the second LED 3-2 are respectively arranged in two first wirings 10. The first sub-pixel sp1 further includes a third LED 3-3. The third LED 3-3 and the second LED 3-2 are connected in series in one first sub-wiring 11. The third LED 3-3 is electrically connected to the second electrode 2. The second LED 3-2 is electrically connected to the second electrode 2. The first LED 3-1 and the second LED 3-2 are both electrically connected to the first electrode 1. A segment of the auxiliary power supply line 8 is reused as the first electrode. In this embodiment, two ends of the auxiliary power supply line 8 are connected two first power supply lines 4 respectively, thereby reducing the voltage drop during the transmission of the first power supply signal and improving the in-plane uniformity.

In the above embodiments, the first color sub-pixel sp1 and the first power supply line 4 are adjacent to each other along the first direction x. FIG. 16 is a partial schematic diagram of another display panel. In some other embodiments, as shown in FIG. 16, in the pixel unit P, the first color sub-pixel sp1 is located between other two sub-pixels sp.

In some embodiments, as shown in FIG. 4, FIG. 9 and FIG. 15, a length of the first LED 3-1 along the first direction x is smaller than a length of the first LED 3-1 along the second direction y, a length of the second LED 3-2 along the first direction x is smaller than a length of the second LED 3-2 along the second direction y, and the first LED 3-1 and the second LED 3-2 are both vertical type LEDs. The first LED 3-1 and the second LED 3-2 are both in strip shapes. Long sides of the first LED 3-1 and the second LED 3-2 extend along the second direction y. That means, the disposing manner of the first LED 3-1 and the second LED 3-2 in the first sub-pixel sp1 is the same. The extending direction of the long sides of the first LED 3-1 and the second LED 3-2 is the same as the extending direction of the first power supply line 4. In addition, a length of the LED 3 in the second color sub-pixel sp2 along the first direction x is smaller than a length of the LED 3 in the second color sub-pixel sp2 along the second direction y, and a length of the LED 3 in the third color sub-pixel sp3 along the first direction x is smaller than a length of the LED 3 in the third color sub-pixel sp3 along the second direction y. That means, the long sides of the LEDs 3 in the second color sub-pixel sp2 and the third color sub-pixel sp3 in the display unit P also extend along the second direction y. With such configuration, the arrangement manner of the LEDs in the first color sub-pixel sp1 is similar to the arrangement manner of the LEDs in other color sub-pixels sp, which simplifies the wiring manner of the driving circuit in the display panel. In addition, the first color sub-pixel sp1 occupies less space along the first direction x, avoiding adversely affecting the resolution of the display panel if the length of the pixel unit P along the first direction x is increased.

In some embodiments, as shown in FIG. 4, FIG. 10 or FIG. 15, the first LED 3-1 and the second LED 3-2 are both in strip shapes. The long sides of the first LED 3-1 and the second LED 3-2 extend along the second direction y. A length of the third LED 3-3 along the first direction x is greater than a length of the third LED 3-3 along the second direction y. In this embodiment, the first LED 3-1, the second LED 3-2 and the third LED 3-3 are all in a flip-chip structure. The LEDs 3 in the first color sub-pixel sp1 are of the same type, the manufacturing process of the same type of LED chips is uniform and low cost. Moreover, when transferring the LEDs, the same transfer process and transferring tool can be used, reducing the manufacturing cost of the display panel. In addition, the extending direction of the long side of the third LED 3-3 intersects with the extending direction of the long side of the first LED 3-1 and the extending direction of the long side of the second LED 3-2. In other words, the first LED 3-1 and the second LED 3-2 are arranged longitudinally, while the third LED 3-3 is arranged transversely. Such configuration makes the arrangement of the LEDs in the first color sub-pixel sp1 more compact, and is conducive to reducing the space occupied by the first color sub-pixel sp1, such that the light-transmitting region 30 in the pixel unit P has a large area, improving the display effect when the display panel is applied in the transparent display.

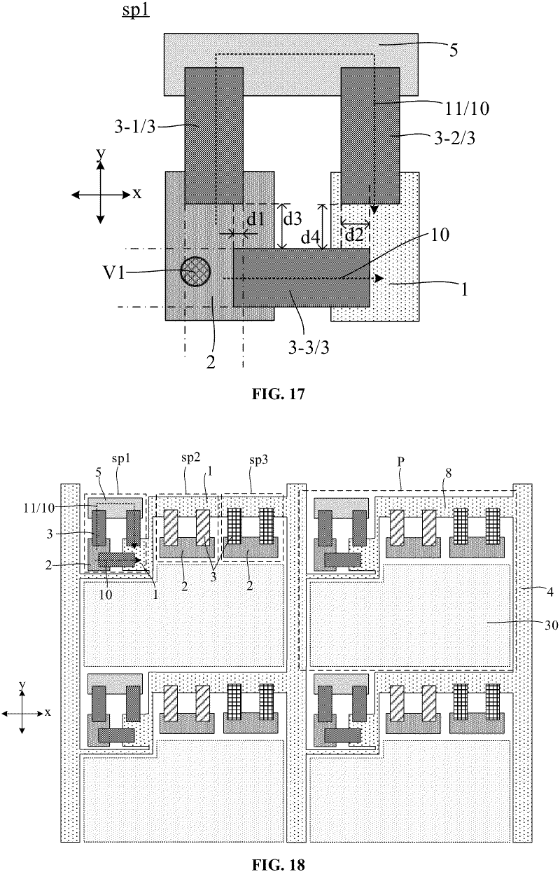

FIG. 17 is a partial schematic diagram of another display panel according to some embodiments of the present disclosure. FIG. 17 only shows the region of the first color sub-pixel sp1. The first color sub-pixel sp1 shown in FIG. 1 is taken as an example. As shown in FIG. 17, the first color sub-pixel sp1 includes a first LED 3-1, a second LED 3-2, and a third LED 3-3. The first LED 3-1 and the third LED 3-3 are electrically connected to the second electrode 2 respectively. The first LED 3-1 and the second LED 3-2 are connected in series in the first sub-wiring 11. The third LED 3-3 is arranged in another first wiring 10. The second electrode 2 is connected to the pixel circuit (not shown in FIG. 17) through the first via V1. For the connection manner of the second electrode 2 and the pixel circuit, references can be made to the embodiments of FIG. 5 and FIG. 6. The first via V1 is located on the extension line of the third LED 3-3 along the first direction x, and is also located on the extension line of the first LED 3-1 along the second direction y. It can be understood that the extension line of the third LED 3-3 and the extension line of the first LED 3-1 both have certain line widths. In this embodiment, the first via V1 and the first LED 3-1 do not overlap, and the first via V1 and the third LED 3-3 do not overlap, such that there is a safety distance between the first LED 3-1 and the third LED 3-3. The first LED 3-1 and the third LED 3-3 are arranged in two first wirings 10 respectively. During the manufacturing process of the display panel, the first LED 3-1 and the third LED 3-3 are transferred by two transfer processes respectively. After the first transfer process, the transferred LED 3 causes fluctuations in the periphery of its position, because the LED has a certain thickness making the position of the transferred LED 3 higher than the position where no transferred LED 3 is located. If the distance between the first LED 3-1 and the third LED 3-3 is small, the transferring yield of the second transfer process is affected. In this embodiment, the safety distance between the first LED 3-1 and the third LED 3-3 ensures that the transferred LED 3 transferred by the first transfer process does not affect the yield of the second transfer process when the first LED 3-1 and the third LED 3-3 are transferred by two transfer processes respectively.

In some embodiments, as shown in FIG. 17, along the second direction y, the first LED 3-1 partially overlaps with the third LED 3-3, the second LED 3-2 partially overlaps with the third LED 3-3, and the first LED 3-1, the second LED 3-2 and the third LED 3-3 are approximately arranged in a shape of a Chinese Character “ [symbol] ”. The overlap part of the third LED 3-3 and the first LED 3-1 has a length d1 along the first direction x. The overlap part of the third LED 3-3 and the second LED 3-2 has a length d2 along the first direction x. The distance d1 and the distance d2 satisfy d1<d2. Each of the first LED 3-1 and the third LED 3-3 overlaps with and is electrically connected to the second electrode 2. With the configuration that the second LED 3-2 and the third LED 3-3 overlap along the second direction y and the overlap part has a longer length along the first direction x, it is ensured that the third LED 3-3 avoids the first via V1 at the position of the second electrode 2, such that the third LED 3-3 corresponds to the flat part of the second electrode 2, ensuring the yield of the transferring of the third LED 3-3.

Along the second direction y, the first LED 3-1 partially overlaps with the third LED 3-3, and the second LED 3-2 partially overlaps with the third LED 3-3. Along the second direction y, a distance d3 between the first LED 3-1 and the third LED 3-3 satisfies d3≥10µm, and a distance d4 between the second LED 3-2 and the third LED 3-3 satisfies d4≥10µm. According to a manufacturing method, during the formation of the first color sub-pixel sp1, the first LED 3-1 and the second LED 3-2 are transferred by the first transfer process to form one first sub-wiring 11, and the third LED 3-3 is transferred by the second transfer process to form another first wiring 10. That means, after the first LED 3-1 and the second LED 3-2 are transferred, the third LED 3-3 is transferred to the corresponding position in the first sub-pixel sp1. By setting an enough safety distance between the third LED 3-3 and the first LED 3-1 and an enough safety distance between the third LED 3-3 and the second LED 3-2, it is ensured that the fluctuation caused by the transferred first LED 3-1 and the transferred second LED 3-2 does not affect the transfer process of the third LED 3-3, thereby improving the yield of the transferring of the third LED 3-3.

In some embodiments, as shown FIG. 4, FIG. 7 or FIG. 10, the three second electrode 2 of the three sub-pixels sp in the pixel unit P are arranged along the first direction x. In the first color sub-pixel sp1, the second electrode 2 extends along the second direction y, and M LEDs 3 in the M first wirings 10 are arranged along the second direction y and electrically connected to the second electrode 2. In this embodiment, the extending direction of the second electrode 2 in the first color sub-pixel sp1 and the arrangement direction of the M LEDs 3 connected to the second electrode 2 are set. Accordingly, two LEDs 3 in the first color sub-pixel sp1 and arranged along the first direction x are connected in series to form the first sub-wiring 11. During the manufacturing process of the display panel, firstly, a set of LEDs are transferred to form the first sub-wiring 11, and then another set of LEDs are transferred to form another first wiring 10 as the redundancy wiring. The arrangement position of the LED 3 in at least one first sub-wiring 11 in the first color sub-pixel sp1 is the same as the arrangement position of the LED 3 in another color sub-pixels sp, improving the regularity of the distribution of light-emitting positions (the arrangement positions of the LEDs) of the sub-pixels sp. When the light emitted by the first sub-wiring 11 contributes the light emitting of the first color sub-pixel sp1, the color mixing of the lights emitted by the three color sub-pixels has a better effect.

In some embodiments, as shown in FIG. 9, FIG. 13 or FIG. 14, the three second electrodes 2 of the three sub-pixels in the pixel unit P are arranged along the first direction x. In the first color sub-pixel sp1, the second electrode 2 extends along the first direction x, and M LEDs 3 in the M first wirings 10 are arranged along the first direction x and electrically connected to the second electrode 2. In this embodiment, the M LEDs connected to the second electrode 2 in the first color sub-pixel sp1 are arranged along the first direction x, and the second electrode 2 extends along the first direction x. When other color sub-pixels sp also include wirings connected in parallel, the second electrodes 2 in the sub-pixels sp have a substantially same shape. In conjunction with the configuration the second electrodes 2 of the three color sub-pixels sp are arranged along the same direction, it is easy to realize that the relative positions of the second electrodes 2 in the sub-pixels sp with respect to the corresponding pixel circuits are substantially the same, which is convenient to the layout design of the pixel circuit in the display panel and the reduction of the wiring design.

In some embodiments, as shown in FIG. 1, FIG. 14 or FIG. 15, the display panel further includes first power supply lines 4 extending along the second direction y and an auxiliary power supply line 8 extending along the first direction x. The first power supply line 4 is electrically connected to the first electrode 1. At least one end of the auxiliary power supply line 8 is electrically connected to the first power supply line 4. In the first color sub-pixel sp1, each of the M first wirings includes one LED 3 electrically connected to the second electrode 2 and another one LED 3 electrically connected to the first electrode 1, and the first electrode 1 is connected to the first power supply line 4 though the auxiliary power supply line 8. In this embodiment, the auxiliary power supply line 8 is provided and electrically connected to the first power supply line 4, and the extending direction of the auxiliary power supply line 8 is the same as the arrangement direction of the three color sub-pixels sp. In this way, the LEDs in the three color sub-pixels sp can be connected to the first power supply line 4 through the auxiliary power supply line 8. The three colors sub-pixels sp in the pixel unit may share one auxiliary power supply line 8, which can simplify the wiring of the display panel and reduce the space of the non-light-transmitting region.

In some embodiments, each of the two ends of the auxiliary power supply line 8 is connected to one first power supply line 4. FIG. 18 is a partial schematic diagram of another display panel according to some embodiments of the present disclosure. FIG. 18 shows multiple pixel units P, and the structure of the pixel unit P shown in FIG. 4 is taken as an example for illustration. As shown in FIG. 18, the display panel includes first power supply lines 4 extending along the second direction y and auxiliary power supply lines 8 extending along the first direction x. Each of the two ends of the auxiliary power supply line 8 is connected to one first power supply line 4. The first power supply lines 4 cross the auxiliary power supply lines 8 to form a mesh structure. Such configuration can reduce the overall resistance, reduce the voltage drop in the transmission of the first power supply signal, and improve the in-plane uniformity.

In some embodiments, as shown in FIG. 7, FIG. 9, FIG. 10, FIG. 11, FIG. 12 or FIG. 13, the display panel includes first power supply lines 4 extending along the second direction y, and the first electrode 1 is electrically connected to the first power supply line 4. In the first color sub-pixel sp1, each of the M first wirings 10 includes one LED 3 electrically connected to the second electrode 2, and the LED 3 in at least one first wiring of the M first wirings 10 is directly electrically connected to the first power supply line 4. For example, the LED 3 in the first sub-wiring 11 is directly electrically connected to the first power supply line 4. For another example, the LED 3 in the first wiring 10 including only one LED 3 is directly electrically connected to the first power supply line 4. Such configuration can reduce the area occupied by the first color sub-pixel sp1, thereby increasing the area of the light-transmitting region 30 in the pixel unit P and improving the display effect when the display panel is applied in the transparent display.

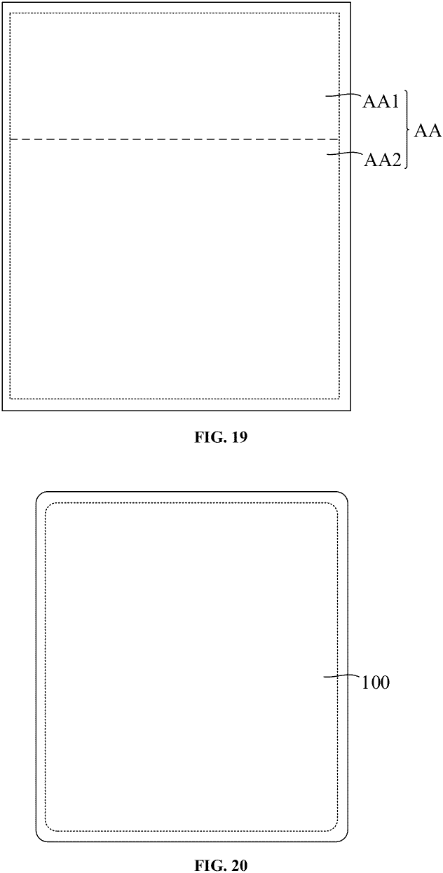

FIG. 19 is a partial schematic diagram of another display panel according to some embodiments of the present disclosure. In some embodiments, as shown in FIG. 19, a display region AA of the display panel includes a first display region AA1 and a second display region AA2. The value of M (the number of the first wirings) of the first color sub-pixel sp1 in the first display region AA1 is different from the value of M (the number of the first wirings) of the first color sub-pixel sp1 in the second display region AA2. The sizes relationship between the first display region AA1 and the second display region AA2, and the locations of the first display region AA1 and the second display region AA2 in the display region AA are not limited in embodiments of the present disclosure. In embodiments of the present disclosure, at different positions of the display region AA, the number of the wirings connected in parallel in the first color sub-pixel sp1 is different.

In some embodiments, in applications, the first display region AA1 and the second display region AA2 have different luminance requirements for the first color sub-pixel sp1. With the configuration that the M value of the first color sub-pixel sp1 in the first display region AA1 is different from the M value of the first color sub-pixel sp1 in the second display region AA2, it is realized that the luminance of the first color sub-pixel sp1 in the first display region AA1 is different from the luminance of the first color sub-pixel sp1 in the second display region AA2, thereby reducing the power consumption.

In some embodiments, since the first display region AA1 and the second display region AA2 are located at different positions of the display panel, the transferring yield of the LEDs in the first display region AA1 may be different from the transferring yield of the LEDs in the second display region AA2. With the configuration that the M value of the first color sub-pixel sp1 in the first display region AA1 is different from the M value of the first color sub-pixel sp1 in the second display region AA2, the region with a poor transferring yield has a larger M value. The number of times of the transfer process for forming the first color sub-pixel sp1 in the first display region AA1 may be different from the number of times of the transfer process for forming the first color sub-pixel sp1 in the second display region AA2, ensuring that the first color sub-pixels sp1 in the first display region AA1 and the second display region AA2 all can emit light normally.

Embodiments of the present disclosure further provide a display device. FIG. 20 is a schematic diagram of a display device according to some embodiments of the present disclosure. As shown in FIG. 20, the display device includes the display panel 100 provided in any embodiment of the present disclosure. The structure of the display panel 100 has been described in the foregoing embodiments, and details are not described herein again. The display device provided by the embodiment of the present disclosure may be a display product such as a mobile phone, a tablet computer, a television, a notebook computer, or an intelligent wearable product.

The above descriptions are merely exemplary embodiments of the present disclosure, and are not intended to limit the present disclosure. Any modifications, equivalent replacements, improvements, and the like made within the principle of the present disclosure shall fall within the protection scope of the present disclosure.

Finally, it should be noted that the foregoing embodiments are merely intended to describe and not to limit the technical solutions of the present disclosure. Although the present disclosure has been described in detail with reference to the foregoing embodiments, persons skilled in the art should understand that they can still make modifications to the technical solutions described in the foregoing embodiments or make equivalent replacements to some or all of the technical features thereof. These modifications or replacements do not make the essence of the corresponding technical solutions deviate from the scope of the technical solutions of the embodiments of the present disclosure.

What is claimed is:

1. A display panel comprising a plurality of sub-pixels, wherein the plurality of sub-pixels comprises at least one first color sub-pixel, wherein one of the at least one first color sub-pixel comprises M first wirings connected in parallel, wherein the M first wirings comprise at least one first sub-wiring, wherein each of the at least one first sub-wiring comprises N light-emitting diodes (LEDs) connected in series, where M and N are positive integers, M≥2, and N≥2.

2. The display panel according to claim 1, wherein the M first wirings further comprise at least one second sub-wiring, wherein one of the at least one second sub-wiring comprises only one LED.

3. The display panel according to claim 1, wherein LEDs in at least two first wirings of the M first wirings are all flip-chip type LEDs, and at least one of the at least two first wirings is one of the at least one first sub-wiring.

4. The display panel according to claim 1, wherein one of the at least one first color sub-pixel comprises at least one vertical type LED; and
the display panel further comprises:
a connection line directly connected to the at least one vertical type LED; and
a substrate, wherein the connection line is located on a side of one of the at least one vertical type LED away from the substrate and is made of a transparent material.

5. The display panel according to claim 1, wherein each of the plurality of sub-pixels comprises a first electrode and a second electrode, wherein one of the first electrode and the second electrode is connected to a positive power supply voltage, and the other one of the first electrode and the second electrode is connected to a negative power supply voltage; the first electrodes of the plurality of sub-pixels are electrically connected to each other; and the second electrodes of the plurality of sub-pixels are independent from each other,
the plurality of sub-pixels further comprises at least one second color sub-pixel and at least one third color sub-pixel, wherein one first color sub-pixel of the at least one first color sub-pixel, one second color sub-pixel of the at least one second color sub-pixel, and one third color sub-pixel of the at least one third color sub-pixel form a pixel unit, and
the second electrodes of the first color sub-pixel, the second color sub-pixel, and the third color sub-pixel in the pixel unit are arranged along a first direction.

6. The display panel according to claim 5, wherein each of the M first wirings comprises one LED electrically connected to the second electrode, and the M LEDs of the M first wirings connected to the second electrode comprise a first LED, and
the first color sub-pixel further comprises a second LED that is adjacent to the first LEDs along the first direction.

7. The display panel according to claim 6, wherein the first LED and the second LED are connected in series in one of the at least one first sub-wiring, the second electrode and the first electrode of the first color sub-pixel are adjacent to each other along the first direction, and the second LED is electrically connected to the first electrode.

8. The display panel according to claim 7, wherein the first color sub-pixel further comprises a third LED, a first end of the third LED is electrically connected to the second electrode, a second end of the third LED and the second LED are connected to the first electrode, and the third LED, the first LED, and the second LED are arranged in a shape of a Chinese character“ [symbol] ”.

9. The display panel according to claim 7, further comprising:
a first power supply line extending along a second direction intersecting with the first direction,
wherein the first electrode is connected to the first power supply line,
the first color sub-pixel further comprises a third LED, wherein a first end of the third LED is electrically connected to the second electrode,
the first electrode of the first color sub-pixel comprises a first sub-electrode and a second sub-electrode, wherein the second LED is electrically connected to the first sub-electrode, the first sub-electrode and the second electrode are arranged along the first direction, a second end of the third LED is electrically connected to the second sub-electrode, and a segment of the first power supply line is reused as the second sub-electrode, and
the third LED is a vertical type LED, and the third LED overlaps with the second electrode or the first power supply line.

10. The display panel according to claim 6, wherein the first LED and the second LED are arranged in two first wirings of the M first wirings, respectively, and the second LED is electrically connected to the second electrode, and
the first LED is arranged in one first sub-wiring of the at least one first sub-wiring, the one first sub-wiring further comprises a fourth LED, and the fourth LED and the first LED are arranged along a second direction intersecting with the first direction.

11. The display panel according to claim 10, further comprising:
at least one first power supply line each extending along the second direction; and
an auxiliary power supply line extending along the first direction,
wherein the first electrode is connected to one of the at least one first power supply line, and at least one end of the auxiliary power supply line each is electrically connected to one of the at least one first power supply line, and
wherein the first electrode of the first color sub-pixel comprises a first sub-electrode and a second sub-electrode, the second LED is electrically connected to the first sub-electrode, a segment of the auxiliary power supply line is reused as the first sub-electrode, an end of the fourth LED is electrically connected to the second sub-electrode, and a segment of one of the at least one first power supply line is reused as the second sub-electrode.

12. The display panel according to claim 11, wherein the fourth LED is a vertical type LED, and
the fourth LED overlaps with one of the at least one first power supply line; or the fourth LED and the first LED are connected in series with each other through a connection electrode, and the fourth LED overlaps with the connection electrode.

13. The display panel according to claim 11, wherein the first LED and the fourth LED are both vertical type LEDs, the first LED overlaps with the second electrode, and the fourth LED overlaps with the auxiliary power supply line.

14. The display panel according to claim 6, further comprising:
at least one first power supply line each extending along a second direction, the second direction intersecting with the first direction; and
an auxiliary power supply line extending along the first direction,
wherein the first electrode is connected to one of the at least one first power supply line, and at least one end of the auxiliary power supply line each is electrically connected to one of the at least one first power supply line,
the first LED and the second LED are arranged in two first wirings of the M first wirings, respectively,
wherein the first color sub-pixel further comprises a third LED that is connected in series with the second LED in one of the at least one first sub-wiring, and the third LED is electrically connected to the second electrode, and
the first LED and the second LED are both electrically connected to the first electrode, and a segment of the auxiliary power supply line is reused as the first electrode.

15. The display panel according to claim 6, wherein a length of the first LED along the first direction is smaller than a length of the first LED along a second direction intersecting the first direction,
a length of the second LED along the first direction is smaller than a length of the second LED along the second direction, and
the first color sub-pixel further comprises a third LED, and a length of the third LED along the first direction is greater than a length of the third LED along the second direction.

16. The display panel according to claim 6, further comprising a pixel circuit electrically connected to the second electrode s through a first via,
wherein in the first color sub-pixel, at least one LED that is directly and electrically connected to the second electrode does not overlap with the first via,
the first color sub-pixel further comprises a third LED electrically connected to the second electrode, wherein the first via is located on both an extension line of the third LED along the first direction and an extension line of the first LED along a second direction, the second direction intersecting the first direction.

17. The display panel according to claim 16, wherein along the second direction, the first LED partially overlaps with the third LED, and the second LED partially overlaps with the third LED,
a length d1 of an overlap part of the third LED and the first LED along the first direction and a length d2 of an overlap part of the third LED and the second LED along the first direction satisfy d1< d2.

18. The display panel according to claim 5, wherein in the first color sub-pixel, the second electrode extends along a second direction intersecting with the first direction, and M LEDs in the M first wirings are arranged along the second direction and electrically connected to the second electrode.

19. The display panel according to claim 5, wherein in the first color sub-pixel, the second electrode extends along the first direction, and M LEDs in the M first wirings are arranged along the first direction and electrically connected to the second electrode.

20. The display panel according to claim 5, further comprising:
at least one first power supply line each extending along a second direction, the second direction intersecting with the first direction; and
an auxiliary power supply line extending along the first direction,
wherein the first electrode is electrically connected to one of the at least one first power supply line, and at least one end of the auxiliary power supply line each is electrically connected to one of the at least one first power supply line, and
in the first color sub-pixel, each of the M first wirings comprises one LED electrically connected to the second electrode and another one LED electrically connected to the first electrode, and the first electrode is electrically connected to one of the at least one first power supply line though the auxiliary power supply line.

21. The display panel according to claim 5, further comprising:
first power supply lines each extending along a second direction intersecting with the first direction, the first electrode being electrically connected to one of the first power supply lines,
wherein in the first color sub-pixel, each of the M first wirings comprises one LED electrically connected to the second electrode, and a LED in at least one first wiring of the M first wirings is directly and electrically connected to one of the first power supply lines.

22. The display panel according to claim 5, wherein the pixel unit comprises a light-transmitting region and a non-light-transmitting region, and LEDs in the first color sub-pixel, the second color sub-pixel, and the third color sub-pixel are located in the non-light-transmitting region.

23. The display panel according to claim 5, wherein the second color sub-pixel comprises at least two second wirings connected in parallel and arranged along the first direction, and each of the least two second wirings comprises one LED,
the third color sub-pixel comprises at least two third wirings connected in parallel and arranged along the first direction, and each of the least two third wirings comprises one LED,
a length of the LED in the second color sub-pixel along the first direction is smaller than a length of the LED in the second color sub-pixel along a second direction intersecting with the first direction, and
a length of the LED in the third color sub-pixel along the first direction is smaller than a length of the LED in the third color sub-pixel along the second direction.

24. The display panel according to claim 1, further comprising:
a first power supply line;
a substrate; and
a pixel circuit located at a side of the substrate,
wherein each of the plurality of sub-pixels comprises a first electrode and a second electrode, the first electrodes of the plurality of sub-pixels are electrically connected to each other, and the second electrodes of the plurality of sub-pixels are independent from each other,
the first electrode is electrically connected to the first power supply line, and the first power supply line, the first electrode, and the second electrode are arranged in a same layer, and
a layer of the second electrode is located at a side of the pixel circuit away from the substrate, LEDs in the plurality of sub-pixels are located at a side of the layer of the second electrode away from the pixel circuit, and the pixel circuit is electrically connected to the second electrode through a via running through an insulation layer.

25. The display panel according to claim 1, wherein at least one first color sub-pixel comprises a plurality of first color sub-pixel, a display region of the display panel comprises a first display region and a second display region, at least one of the plurality of first color sub-pixels is located in the first display region, at least another one of the plurality of first color sub-pixels is located in the second display region, a first number of first wirings in one first color sub-pixel of the at least one of the plurality of first color sub-pixels is different from a second number of first wirings in one first color sub-pixel of the at least another one of the plurality of first color sub-pixels.

26. A display device comprising a display panel, wherein the display device comprises a plurality of sub-pixels, wherein the plurality of sub-pixels comprises at least one first color sub-pixel, wherein one of the at least one first color sub-pixel comprises M first wirings connected in parallel, wherein the M first wirings comprise at least one first sub-wiring, wherein each of the at least one first sub-wiring comprises N light-emitting diodes (LEDs) connected in series, where M and N are positive integers, M≥2, and N≥2.
